(19) United States
(12) Patent Application Publication
(10) Pub. No.: US 2026/0076098 A1
(43) Pub. Date: Mar. 12, 2026

(54) Oriented Metal Electrode Unit and Preparation Methods and Applications Thereof

(71) Applicants: LoMaRe Chip Technology Changzhou Co., Ltd., Changzhou City (CN); LoMaRe Technologies Limited, London (GB)

(72) Inventors: Fengzhi Yu, Changzhou City (CN); Xudong Sun, Changzhou City (CN); Andrei Paul Mihai, London (GB); Bin Zou, London (GB); Jan Zemen, London (GB)

(21) Appl. No.: 18/827,111

(22) Filed: Sep. 6, 2024

(30) Foreign Application Priority Data
Jul. 7, 2023 (CN) 202310834710.3

(51) Int. Cl. H10N 50/80; H10B 61/00; H10N 50/01; H10N 70/00

(52) U.S. Cl. CPC H10N 50/80; H10B 61/00; H10N 50/01; H10N 70/011; H10N 70/841

(57) ABSTRACT

The present invention provides an oriented metal electrode unit and preparation methods and applications thereof, relating to the technical field of semiconductor devices, comprising: a Si substrate covered with an amorphous SiO₂ layer; a buffer layer, covered on said SiO₂ layer, comprising Ta, Cr, TiN, TaN or MgO; a seed layer, covered on said buffer layer, comprising A₃BN, wherein A=Cu or Fe; B=Pd or Pt; or MnₓN₁₋ₓ, wherein 0<x<1; a metal electrode layer, prepared on the basis of said seed layer, having a (00l) crystalline orientation; said buffer layer, said seed layer and said metal electrode layer having consistent lattice constants, solving the problem of existing semiconductor devices having poor performance in obtaining crystalline metal electrodes on amorphous SiO₂ layers.

### TECHNICAL FIELD

The present invention relates to the technical field of semiconductor devices, and in particular relates to an oriented metal electrode unit and preparation methods and applications thereof.

### BACKGROUND TECHNOLOGY

In most semiconductor devices, only the conductivity and stability of the metal as an electrode is considered, so the metal is usually amorphous. However, due to the large number of defects in amorphous materials, metal electrodes with a high degree of crystallinity are required for specific devices such as MRAMs, and other monolithic epitaxial spintronic devices.

Semiconductor devices need to be integrated on silicon circuits, such as CMOS, for a wider range of applications. However, the top layer of CMOS is usually an amorphous SiO₂ passivation layer, so it remains a challenge to obtain crystalline metal electrodes on the amorphous SiO₂ layer for better performance.

### SUMMARY OF THE INVENTION

In order to overcome the above technical drawbacks, the purpose of the present invention is to provide an oriented metal electrode unit and preparation methods and applications thereof, aiming at solving the problem of poor performance of existing semiconductor devices in obtaining crystalline metal electrodes on amorphous SiO₂ layers.

The present invention discloses an oriented metal electrode unit, comprising:

A Si substrate covered with an amorphous SiO₂ layer;

A buffer layer, covering said SiO₂ layer, comprising Ta, Cr, TiN, TaN, MgO or CrN;

A seed layer, covering said buffer layer, comprising A₃BN, wherein A=Cu or Fe; B=Pd or Pt; or MnₓN₁₋ₓ, wherein 0<x<1;

A metal electrode layer, prepared on the basis of said seed layer, having (00l) crystalline orientation;

Said seed layer and said metal electrode layer have matching lattice constants.

Preferably, said Si substrate containing CMOS circuits.

Preferably, said metal electrode layer comprises Pd, Pt.

Preferably, the thickness of said Si substrate and amorphous SiO₂ layer is 1 to 5000 nm.

Preferably, the roughness of said amorphous SiO₂ layer is less than 5 nm.

Preferably, the thickness of said buffer layer is 2 to 100 nm;

The thickness of said seed layer is 2 to 200 nm;

The thickness of said metal electrode layer is 10 to 500 nm.

The present invention also provides methods of preparing an oriented metal electrode unit for preparing the oriented metal electrode described in any one of the foregoing, comprising: preparing an amorphous SiO₂ layer on a Si substrate;

Preparing a buffer layer on said amorphous SiO₂ layer, wherein said buffer layer comprises Ta, Cr, TiN, TaN or MgO;

Preparing a seed layer on said buffer layer, wherein said seed layer comprises A₃BN or MnₓN₁₋ₓ, A=Cu or Fe; B=Pd or Pt; O<x<1;

Preparing a metal electrode layer with (00l) crystalline orientation on said seed layer.

Preferably, the growth temperatures of both said buffer layer and said seed layer are both below 450° C.

Preferably, the buffer layer and seed layer are prepared by magnetron sputtering, atomic layer deposition, pulsed laser beam deposition or molecular beam epitaxy.

The present invention also provides applications of an oriented metal electrode unit, said oriented metal electrode unit, being an oriented metal electrode unit as described in any one of the claims prepared by any one of the preparation methods, is used as a crystalline electrode in electronic devices, wherein said electronic devices comprises a spintronic device, a memory, a magnetic memory element and a ferroelectric tunnelling device.

With the adoption of the above technical solutions, the following beneficial effects are achieved compared to the prior art:

The present application provides an oriented metal electrode unit and preparation methods and application thereof, forming the oriented metal electrode unit comprising a substrate (Si or Si containing CMOS), an amorphous SiO₂ layer, a buffer layer, a seed layer, and a crystalline metal electrode layer, wherein the metal electrode layer uses the buffer layer and the seed layer as the bottom layer, and a metal or nitride or oxide is sputtered or deposited to form the buffer layer and the seed layer, the metal electrode crystallises in the direction of (00l) (where l is generally an integer number in the range of 1 to 9), thereby obtaining a high crystallinity metal electrode on an amorphous substrate to be a crystalline electrode forming a part of spintronic devices, such as electronic devices applied in spin valves, tunneling magnetic devices, MRAM, SOT-MRAM, and ferroelectric tunneling devices.

### BRIEF DESCRIPTION OF DRAWINGS

FIG. 1 is a schematic structural diagram of Embodiment 1 of an oriented metal electrode unit and preparation methods and applications thereof described in the present invention;

FIG. 2 shows an X-ray diffraction pattern of a metal electrode unit prepared with a certain substrate, a buffer layer, a seed layer, and a metal electrode layer according to Embodiment 2 of an oriented metal electrode unit and preparation methods and applications thereof described in the present invention;

FIG. 3 shows an X-ray diffraction pattern of a metal electrode unit prepared with another substrate, a buffer layer, a seed layer, and a metal electrode layer of Embodiment 2 of an oriented metal electrode unit and preparation methods and applications thereof described in the present invention;

FIG. 4 shows an X-ray diffraction pattern of a metal electrode unit prepared with another substrate, a buffer layer, a seed layer, and a metal electrode layer of Embodiment 2 of an oriented metal electrode unit and preparation methods and applications thereof described in the present invention;

FIG. 5 shows an X-ray diffraction pattern of a metal electrode unit prepared with another substrate, a buffer layer, a seed layer, and a metal electrode layer in Embodiment 2 of an oriented metal electrode unit and preparation methods and applications thereof described in the present invention;

FIG. 6 shows an X-ray diffraction pattern of a metal electrode unit prepared with another substrate, a buffer layer, a seed layer, and a metal electrode layer of Embodiment 2 of an oriented metal electrode cell and preparation methods and applications thereof described in the present invention;

FIG. 7 shows an X-ray diffraction pattern of a metal electrode unit prepared with another substrate, a buffer layer, a seed layer, and a metal electrode layer of Embodiment 2 of an oriented metal electrode unit and preparation methods and applications thereof described in the present invention;

FIG. 8 shows a flowchart of Embodiment 2 of an oriented metal electrode unit and preparation methods and applications thereof as described in the present invention.

### DETAILED EMBODIMENTS

The advantages of the present invention are further described below in connection with the accompanying drawings and specific embodiments.

Exemplary embodiments will be described in detail herein, examples of which are represented in the accompanying figures. Where the following description refers to the accompanying drawings, unless otherwise indicated, the same numbers in different accompanying drawings indicate the same or similar elements. The embodiments described in the following exemplary embodiments do not represent all embodiments consistent with the present disclosure. Rather, they are merely examples of devices and methods consistent with some aspects of the present disclosure as detailed in the appended claims.

The terms used in this disclosure are solely for the purpose of describing particular embodiments and are not intended to limit the present disclosure. The singular forms of “a”, “said”, and “the” used in this disclosure and the appended claims are also intended to include the plural forms, unless the context clearly indicates otherwise. It should also be understood that the term “and/or” as used herein refers to and includes any or all of the possible combinations of one or more of the associated listed items.

It should be understood that while the terms first, second, third, etc. may be employed in the present disclosure to describe various pieces of information, such information should not be limited to these terms. These terms are only used to distinguish the same type of information from one another. For example, without departing from the scope of the present disclosure, the first information may also be referred to as the second information, and similarly, the second information may also be referred to as the first information. Depending on the context, the word “if” as used here could be interpreted as “at . . . ”or “when . . . ”or “in response to a determination”.

In the description of the present invention, it is to be understood that the terms “longitudinal”, “lateral”, “upper”, “lower”, “front”, “back”, “left”, “right”, “vertical”, “horizontal”, “top”, “bottom”, “inside”, “outside” etc. indicating orientational or positional relationships based on those shown in the accompanying drawings, and are only to facilitate the description of the present invention and to simplify the description, and are not to indicate or imply that the device or element referred to must have a particular orientation, be constructed and operated with a particular orientation, and therefore are not to be construed as limitations of the present invention.

In the description of the present invention, unless otherwise specified and limited, it is to be noted that the terms “mounted”, “linked”, “connected” are to be understood in a broad sense, e.g., it can be a mechanical connection or an electrical connection, it can be a connection within two elements, it can be a direct connection or an indirect connection through an intermediate medium and the specific meaning of the above terms may be understood by a person of ordinary skill in the art in the light of the specific circumstances.

In the subsequent description, suffixes such as “module”, “part” or “unit” used to denote components are used only to facilitate the description of the present invention and have no specific meaning in themselves. Thus, “module” and “component” can be used interchangeably.

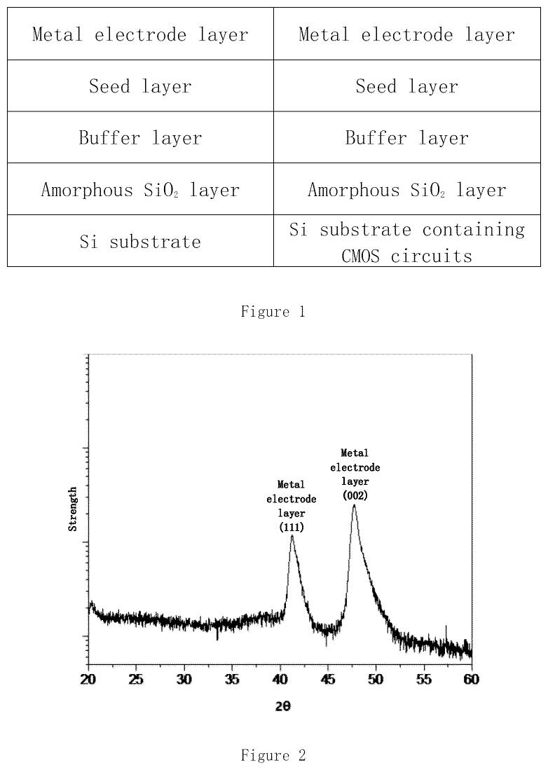

Embodiment 1: The present invention discloses an oriented metal electrode unit, which can be obtained on an amorphous substrate with high crystallinity metal electrodes, so as to realise a wide range of applications in supercapacitors, memory devices, field effect transistors, MEMS, etc., specifically, with reference to FIG. 1, comprising:

Si substrate covered with an amorphous SiO₂ layer; optionally, CMOS circuits may be arranged on said Si substrate, and CMOS circuits may be integrated on the oriented metal electrode unit for application in said semiconductor device.

A buffer layer, covering said SiO₂ layer, including but not limited to Ta (tantalum), Cr (chromium), TiN (titanium nitride), TaN (tantalum nitride), MgO (magnesium oxide), or CrN (chromium nitride);

A seed layer, covering said buffer layer, including, but not limited to, A₃BN, wherein A=Cu (copper) or Fe (iron); B=Pd (palladium) or Pt (platinum); or MnₓN₁₋ₓ, wherein 0<x<1;

A metallic electrode layer, prepared on the basis of said seed layer, having (00l) crystalline orientation;

Said seed layer and said metal electrode layer have matching/similar (within a predetermined error) lattice constants.

Based on the above structure, in the present embodiment, the oriented metal unit comprises a substrate (Si or Si containing CMOS), an amorphous SiO₂ layer, a buffer layer, a seed layer, and a metal electrode layer. The metal electrode layer uses a buffer layer and a seed layer as the bottom layer, and based on the aforementioned buffer layer and seed layer, the metal electrode can crystallise in the orientation of (00l), thereby obtaining a high crystallinity metal electrode on an amorphous (i.e., the aforementioned SiO₂) substrate.

Based on the above structure, preferably, said metal electrode layer comprises Pd, Pt, which can correspond to the above seed layer, forming an oriented metal electrode, or can be other materials that can form a metal electrode.

Further, in the oriented metal electrode unit provided in this embodiment, the thickness of said Si substrate and amorphous SiO₂ layer is 1 to 5000 nm; the roughness of said amorphous SiO₂ layer is less than 5 nm, i.e., maintaining a small roughness on the substrate surface makes the connection to the buffer layer thereon closer. The thickness of said buffer layer is 2 to 100 nm; the thickness of said seed layer is 2 to 200 nm; the thickness of said metal electrode layer is 10 to 500 nm; the buffer layer and the seed layer are used as the bottom layer of the metal electrode layer, having relative small thickness to the metal electrode layer, enables the formation of a metal electrode layer with a specific crystalline orientation, and at the same time realises the application of the oriented metal electrode units.

As an illustration, the amorphous SiO₂ layer formed on the Si substrate as described above may be achieved by thermal oxidation, chemical vapour deposition (CVD, PECVD), or natural oxidation, and the buffer and seed layers as described above may be formed by sputtering or deposition, specifically including but not limited to sputtering, PLD, ALD, or MBE deposition, and finally the metal electrode layer with (00l) crystalline orientation is formed based on the growth of the buffer layer and seed layer as described above, to form the oriented metal electrode unit that can be used to form magnetic tunnel junctions (MTJ) or some other spintronic devices (spintronic devices include, but are not limited to, field effect transistors, memory devices, tunnel junctions, magneto-electrically coupled devices, switchable photovoltaic devices, spintronic valves, and ferroelectric devices) in this embodiment.

Embodiment 2: The present invention also provides preparation methods of an oriented metal electrode for preparing the oriented metal electrode described in any one of the above Embodiment 1, specifically, with reference to FIG. 8, comprising:

S10: Preparing an amorphous SiO₂ layer on a Si substrate.

In this embodiment, an amorphous SiO₂ layer is formed on a Si substrate, which may be formed by, for example, thermal oxidation or vapour deposition, thereby enabling the buffer and seed layers described below to be prepared on an amorphous silicon substrate to form an oriented metal electrode. It should be noted that the electrode structure described above is based on amorphous SiO₂, so optionally CMOS circuits can be directly integrated thereon.

S20: Preparing a buffer layer on said amorphous SiO₂ layer, wherein said buffer layer comprises Ta, Cr, TiN, TaN or MgO.

Specifically, as illustrated, the above buffer layer may be formed by sputtering or deposition of materials including, but not limited to, Ta, Cr, TiN, TaN, or MgO, and, as described above, the thickness of the buffer layer is 2 to 100 nm; and, specifically, the buffer layer is prepared with a growth temperature lower than 450° C., so that it is grown with a preset crystalline orientation and crystallographic distribution.

S30: Preparing a seed layer on said buffer layer, wherein said seed layer comprises A₃BN or MnₓN₁₋ₓ, A=Cu or Fe; B=Pd or Pt; 0<x<1.

Specifically, the above seed layer may also be formed by sputtering or deposition with a thickness of 2 to 200 nm and a growth temperature lower than 450° C., such that it is grown in the (00l) crystalline orientation, such that subsequent metal electrode layers of the metal electrodes will be crystallised in the orientation of (00l), with both having similar (matching) lattice constants, i.e., a similar crystallographic distribution, in order to facilitate the preparation of the oriented metal electrode layer in the following steps.

S40: Preparing a metal electrode layer with (00l) crystalline orientation on said buffer layer.

Specifically, an oriented (i.e., (00l)-crystalline oriented) metal electrode layer is formed based on the growth of the above buffer layer and the seed layer as the bottom layer of the metal electrode layer, and the realisation of a high crystallinity metal electrode on amorphous substrate is obtained with excellent performance.

Specifically, the buffer layer and the seed layer can be prepared by deposition methods including, but not limited to, magnetron sputtering, atomic layer deposition (ALD), pulsed laser beam deposition (PLD), or molecular beam epitaxial deposition (MBE), etc., and other existing deposition methods that can achieve the formation of the above-described oriented metal electrode layer can also be used for this purpose.

By the preparation method provided in this embodiment, an oriented metal electrode unit comprising a substrate (Si or Si containing CMOS), an amorphous SiO₂ layer, a buffer layer, a seed layer, and a crystalline metal electrode layer is formed, wherein the metal electrode layer uses the buffer and the seed layer as the bottom layer, and based on the above mentioned sputtering or deposition of a metal or nitride or oxide to form the buffer layer and the seed layer, the metal electrode will be crystallised in (00l) orientation to form the above-mentioned metal electrode layer, thereby obtaining a high crystallinity metal electrode on an amorphous substrate.

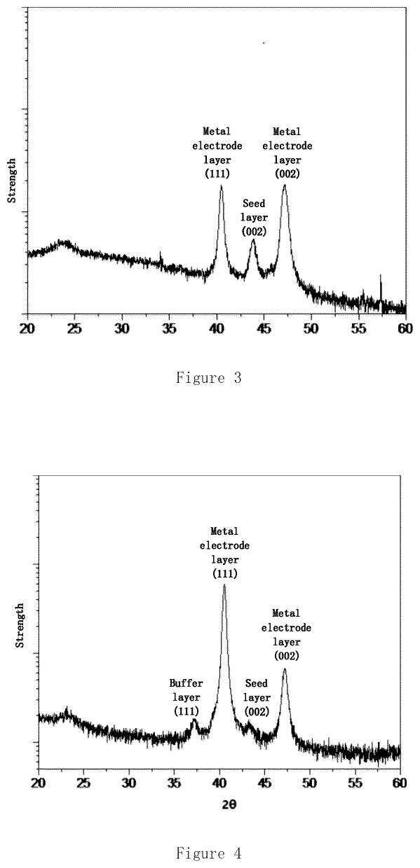

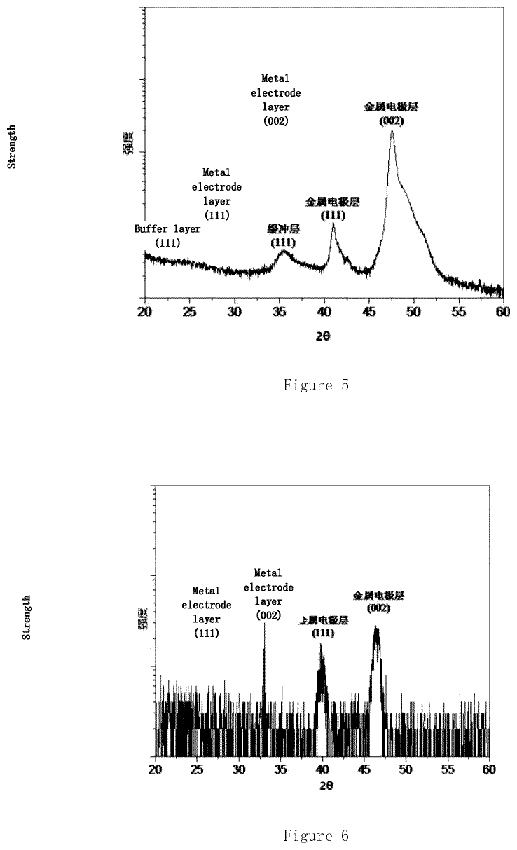

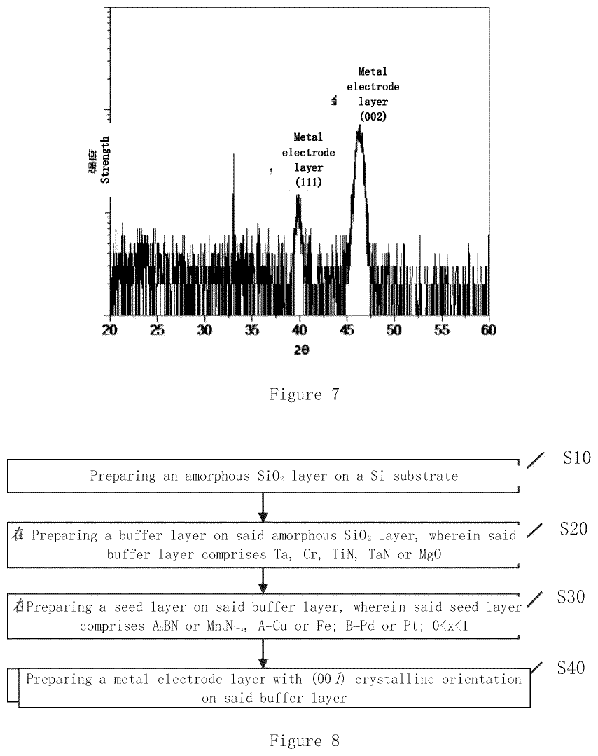

As an example, referring to the X-ray diffraction pattern of FIG. 2-FIG. 7, FIG. 2 shows an X-ray diffraction pattern of an oriented metal electrode unit formed based on a substrate of Si+180 nm SiO₂; a buffer layer of Ta; a seed layer of Cu₃PdN; and a metal electrode layer of Pt; FIG. 3 shows an X-ray diffraction pattern of an oriented metal electrode unit formed based on a substrate of Si+180 nm SiO₂; a buffer layer of Cr; a seed layer of MnN; a metal electrode layer of Pt; FIG. 4 shows the X-ray diffraction pattern of an oriented metal electrode unit formed based on a substrate of Si+180 nm Si0₂; a buffer layer of TiN; a seed layer of MnN; and a metal electrode layer of Pt; FIG. 5 shows the X-ray diffraction pattern of an oriented metal electrode unit formed based on a substrate of Si+180 nm SiO₂; a buffer layer of TaN; a seed layer of Cu₃PdN; a metal electrode layer of Pt; FIG. 6 shows the X-ray diffraction pattern of the oriented metal electrode unit formed based on a substrate of silicon +180 nm Si0₂; a buffer layer of MgO; a seed layer of MnN; a metal electrode layer of Pt; FIG. 7 shows X-ray diffraction pattern of the oriented metal electrode unit formed based on a substrate of silicon+natural oxide layer SiO₂; a buffer layer of TaN; a seed layer of MnN; a metal electrode layer of Pt. As can be seen from FIG. 2-FIG. 7, metal electrodes oriented to be highly crystalline in the orientation of (00l) can be formed.

Embodiment 3: The present invention also provides an application of an oriented metal electrode, said oriented metal electrode being the oriented metal electrode described in any one of Embodiment 1 prepared by any one of the preparation methods in Embodiment 2, as a crystalline electrode in an electronic device, wherein said electronic device comprises a spintronic device, a memory, a magnetic memory element, and a ferroelectric tunnelling device, and specifically, the entire electrode structure based on amorphous SiO₂ can be directly integrated into CMOS. Spintronic devices include, but are not limited to, field effect transistors, memory devices, tunnel junctions, magneto-electric coupling devices, switchable photovoltaic devices, spin valves, and ferroelectric devices, which can be widely used in supercapacitors, memory devices, field effect transistors, MEMS, etc.

It should be noted that the embodiments of the present invention have better implementability, and are not a limitation of the present invention in any form, and any skilled person familiar with the field may use the above disclosed technical content to change or modify to the equivalent of the effective embodiments, as long as they are not deviate from the content of the technical solution of the present invention, any modifications or equivalent changes and modifications made to the above embodiments in accordance with the technical substance of the present invention, still fall in the scope of the technical solution of the present invention.

What is claimed is:

1. An oriented metal electrode unit characterised as comprising:
a Si substrate covered with an amorphous SiO₂ layer;
a buffer layer, covering said SiO₂ layer, comprising Ta, Cr, TiN, TaN, MgO or CrN;
a seed layer, covering said buffer layer, comprising A₃BN, wherein A=Cu or Fe; B=Pd or Pt; or MnₓN₁₋ₓ, wherein 0<x<1;
a metal electrode layer, prepared on the basis of said seed layer, having (00l) crystalline orientation;
said seed layer and said metal electrode layer have matching lattice constants.

2. The oriented metal electrode unit according to claim 1, characterised in that:
said Si substrate containing CMOS circuits.

3. The oriented metal electrode unit according to claim 1, characterised in that:
said metal electrode layer comprises Pd, Pt.

4. The oriented metal electrode unit according to claim 1, characterised in that:
the thickness of said Si substrate and amorphous SiO₂ layer is 1 to 5000 nm.

5. The oriented metal electrode unit according to claim 1, characterised in that:
the roughness of said amorphous SiO₂ layer is less than 5 nm.

6. The oriented metal electrode unit according to claim 1, characterised in that:
the thickness of said buffer layer is 2 to 100 nm;
the thickness of said seed layer is 2 to 200 nm;
the thickness of said metal electrode layer is 10 to 500 nm.

7. A method of preparing the oriented metal electrode unit, characterised in that for preparing the oriented metal electrode described in claim 1, comprising:
preparing an amorphous SiO₂ layer on a Si substrate;
preparing a buffer layer on said amorphous SiO₂ layer, wherein said buffer layer comprises Ta, Cr, TiN, TaN or MgO;
preparing a seed layer on said buffer layer, wherein said seed layer comprises A₃BN or MnₓN₁₋ₓ, A=Cu or Fe; B=Pd or Pt; 0<x<1;
preparing a metal electrode layer with (00l) crystalline orientation on said seed layer.

8. The method of preparation according to claim 1, characterised in that:
the growth temperatures of both said buffer layer and said seed layer are both below 450°C.

9. A method of preparation according to claim 1, characterised in that:
the buffer and seed layers are prepared by magnetron sputtering, atomic layer deposition, pulsed laser beam deposition or molecular beam epitaxy.

10. An application of an oriented metal electrode unit, characterised in that:
said oriented metal electrode unit as a crystalline electrode in electronic devices, wherein said electronic devices comprises a spintronic device, a memory, a magnetic memory element and a ferroelectric tunnelling device.
